(19) United States
(12) Patent Application Publication
(10) Pub. No.: US 2021/0024422 A1
(43) Pub. Date: Jan. 28, 2021

(54) METHOD FOR THE MANUFACTURE, BY STEREOLITHOGRAPHY, OF GREEN PIECES OF CERAMIC OR METAL MATERIAL BY PHOTO-THERMAL ROUTE

(71) Applicant: S.A.S 3DCeram-Sinto, Limoges (FR)

(72) Inventors: Christophe CHAPUT, LE PALAIS-SUR-VIENNE (FR); Richard GAIGNON, SAINT-VRAIN (FR); Cindy SCHICK, LE PALAIS-SUR-VIENNE (FR)

(21) Appl. No.: 16/935,277

(22) Filed: Jul. 22, 2020

(30) Foreign Application Priority Data
Jul. 22, 2019 (FR) 1908279

(51) Int. Cl. C04B 35/50; C04B 35/484; C04B 35/634; B33Y 10/00; B33Y 70/10; B28B 1/00; B22F 3/00

(52) U.S. Cl. CPC C04B 35/50; C04B 35/484; C04B 35/63424; B33Y 10/00; C04B 2235/6026; B28B 1/001; B22F 3/008; C04B 2235/3268; C04B 2235/3246; B33Y 70/10

(57) ABSTRACT

Disclosed is a method for manufacturing, by stereolithography, a green part made of a ceramic or metallic material. Layers based on a curable composition including: the ceramic or metallic material formed by at least one ceramic or metallic powder, respectively, and an organic part including at least one monomer and/or oligomer and at least one initiator for the polymerization of the one or more monomers and/or oligomers, are successively cured by the polymerization according to a pattern defined for each layer. The first layer formed on a construction platform, each other layer being formed and then cured on the preceding layer. As an initiator, at least one thermal initiator is used capable of generating the initiation of a thermal polymerization by the thermal energy released by the ceramic or metallic material, respectively, during exposure to at least one irradiation source chosen from UV, visible or IR irradiation sources.

### BACKGROUND OF THE INVENTION

### Field of the Invention

The present invention relates to a method and a composition for manufacturing green parts of ceramic or metallic material by using stereolithography, said green parts being intended to be subjected to cleaning, debinding and sintering operations in order to obtain finished ceramic or metallic parts.

### Description of the Related Art

Stereolithography generally comprises the following steps, for obtaining these green parts:
building, by computer-aided design, a computer model of the piece to be manufactured, the sizes of the model being slightly larger than those of the piece to be manufactured so as to anticipate a shrinking of the ceramic or metallic material during the manufacturing of the piece; and
manufacturing the piece as follows:
   forming, on a rigid support, a first layer of a photocurable composition comprising at least one ceramic or metallic material, a photocurable monomer and/or oligomer, a photoinitiator and, when appropriate, at least one of the following: a plasticizer, a solvent, a dispersant, or a polymerization inhibitor;
   curing the first layer of the photocurable composition by irradiation (by laser scanning of the free surface of said layer or by using a diode projection system) according to a defined pattern based on the model for said layer, forming a first stage;
   forming, on the first stage, a second layer of the photocurable composition;
   curing the second layer of the photocurable composition, by irradiation according to a pattern defined for said layer, forming a second layer, this irradiation being performed in the same way as the first layer;
   optionally, repeating the above mentioned steps until the green piece is obtained.

Then, in order to obtain the finished part as indicated above, the green piece is cleaned in order to remove the uncured composition; the cleaned green piece is debinded; and the cleaned and debinded green piece is sintered in order to obtain the finished piece.

The part may be manufactured by a paste process or a liquid process.
In a manufacturing by a paste process, the photocurable composition is in the form of a paste while the rigid support is a working tray that supports the different layers of the piece under construction as well as the paste; each of the layers is generally formed by lowering the working tray and spreading paste with a predefined thickness. A paste stock is stored in tanks that are automatically emptied of a predefined amount of paste at each layer using a piston. This creates a bead of paste to be spread over the upper layer of the part being manufactured that has been previously lowered by the working tray. Each layer is generally spread by scraping using a “scraper” blade which sweeps over the working surface of the working tray, for example by advancing in a horizontal rectilinear direction.
In the case of manufacturing by a liquid process, the photocurable composition is in the form of a low viscosity suspension.
   In a first embodiment by a liquid process, the rigid support is a tray which is lowered into a bath of the photocurable suspension in order to cover it with a layer of said suspension, said layer being then cured by irradiation as indicated above. Each of the following layers is then successively formed on this first layer by lowering the tray step by step into the bath so that the upper level of the part being formed is lowered beneath the free surface of the photocurable suspension to form the layer in question, said layer then being subject to irradiation.
   In a second embodiment by a liquid process, the photocurable suspension is contained in a tank with a transparent bottom to allow irradiation, while the part being manufactured is held on a rigid support in the form of a platform that rises step by step. Thus, we start by curing a base layer, then the platform is raised by one step to allow the suspension to form a new layer which we then cure, wherein the operation is successively repeated for each layer.
   In a third embodiment by a liquid process, the photocurable suspension is spread in a layer on a transparent film for irradiation, the film being arranged to unroll horizontally. The part is formed on a rigid platform which is lowered in order to come into contact with the layer which is cured by irradiation through the film. We then unroll a new segment of film coated with a new photocurable layer, and repeat the operation until the construction of the piece is completed.

The various ceramic or metallic powders that are used in stereolithography exhibit UV light absorption behaviors at the wavelength of the UV beam used (for example 355 nm), that may vary from one to the other.

Some powders are very absorbent, such as lanthanum strontium manganite (LSM) ceramic, silicon carbide (SiC) or silver (Ag) powders, while other powders are much less absorbent, such as alumina (Al₂O₃) and zirconia (ZrO₂).

We may thus mention that the ZrO₂ powder absorbs only 8% of UV light at 355 nm, while LSM and SiC each absorb more than 90%.

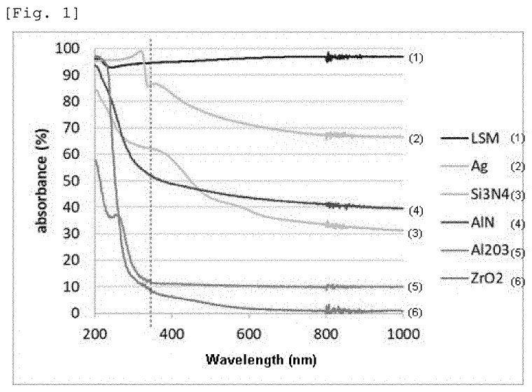

FIG. 1 shows the absorption spectra of certain ceramic/metallic powders.

In these latter cases, the light absorbed by the powder is no longer available for the photoinitiator, and the photopolymerization reaction can, therefore, no longer take place.

In other words, the lack of reactivity of certain photosensitive ceramic or metallic pastes or suspensions to UV exposure makes it difficult, if not impossible, to construct an object by UV stereolithography.

### SUMMARY OF THE INVENTION

To solve this problem, the Applicant incorporated a thermal initiator in a ceramic or metallic paste or suspension in order to use the thermal energy released by ceramic or metallic powders during their exposure to UV-visible light as well as IR light, so as to generate the controlled initiation of the thermal polymerization.

In this case, the absorbance of the ceramic or metallic particles at the working wavelength is therefore favorable, as the light energy absorbed by the ceramic or metallic particles is converted into heat, and as this heat is then absorbed by a thermal initiator to allow polymerization of the resin.

To this end, the present invention relates to a method for manufacturing, by stereolithography, a green part made of a ceramic or metallic material, method according to which the layers based on a curable composition comprising:
said ceramic or metallic material formed by at least one ceramic or metallic powder, respectively; and
an organic part comprising at least one monomer and/or oligomer and at least one initiator for the polymerization of said one or more monomers and/or oligomers,
   are successively cured by said polymerization according to a pattern defined for each layer, the first layer being formed on a construction platform, and each other layer being formed and then cured on the preceding layer,

characterized in that as an initiator, at least one thermal initiator is used which is capable of generating the initiation of a thermal polymerization under the action of the thermal energy released by said ceramic or metallic material, respectively, during exposure of the latter to at least one irradiation source chosen from UV, visible or IR irradiation sources.

The ceramic powder(s) may be chosen from oxide ceramic powders, such as lanthanum strontium manganite ceramic, lanthanum strontium manganite ceramic in mixture with yttrium-stabilized zirconia, zirconia, yttrium-stabilized zirconia, ferrite, and non-oxide ceramic powders, such as silicon carbide, silicon nitride and aluminum nitride.

The metallic powder(s) may be chosen from silver, copper, iron, tungsten and their alloys.

One or more ceramic and/or metallic powders may be used, in particular at a rate of 25 to 65 parts by volume relative to the total volume.

As monomers and/or oligomers entering the organic part of the curable composition according to the invention, polyfunctional (meth)acrylates, such as diethoxylated bisphenol A dimethacrylate, 1,6-hexanediol diacrylate, 3-methyl-1,5-pentanediol diacrylate, trimethylolpropane triacrylate, and mixtures thereof, may be mentioned.

The monomer(s) and/or oligomer(s) may be used at a rate of, in particular, 20 to 50 parts by volume relative to the total volume.

The thermal initiator(s) may be chosen from:
peroxides, such as tert-amyl peroxybenzoate, benzoyl peroxide, 2,2-bis(tert-butylperoxy)butane, 1,1-bis(tert-butylperoxy)cyclohexane, 2,5-bis(tert-butylperoxy)-2,5-dimethylhexane, 2,5-bis(tert-butylperoxy)-2,5-dimethyl-3-hexyne, bis(1-(tert-butylperoxy)-1-methyl ethyl)benzene, 1,1-bis(tert-butylperoxy)-3,3,5-trimethylcyclohexane, tert-butyl peracetate, tert-butyl peroxide, tert-butyl peroxybenzoate, tert-butylperoxy isopropyl carbonate, cyclohexanone peroxide, dicumyl peroxide, lauroyl peroxide, 2,4-pentanedione peroxide, potassium persulfate and ammonium persulfate;
hydroperoxides, such as tert-butyl hydroperoxide, cumene hydroperoxide and peracetic acid;
alkoxyamines, such as N-(2-methylpropyl)-N-(1-diethylphosphono-2,2-dimethylpropyl)-O-(2-carboxyprop-2-yl)hydroxylamine (BlocBuilder® MA); and
azo compounds, such as 1,1′-azobis(cyclohexanecarbonitrile) and 2,2′-azobisisobutyronitrile (AIBN).

In particular, the thermal initiator(s) may be used at a rate of, in particular, 0.5 to 8 parts by volume relative to the total volume.

A curable composition further comprising at least one plasticizer chosen, in particular, from polyethylene glycol, dibutyl phthalate and glycerol (non-exhaustive list), in particular at a rate of 5 to 25 parts by volume relative to the total volume, may be used.

A curable composition further comprising at least one dispersant chosen, in particular, from phosphoric esters, in particular at a rate of 1 to 8 parts by volume relative to the total volume, may be used.

In particular, a curable composition further comprising at least one polymerization inhibitor chosen, in particular, from 4-methoxyphenol and phenothiazine, in particular at a rate of 0.1 to 3 parts by volume relative to the total volume, may be used.

The present invention also relates to a composition for implementing the method as defined above, characterized in that it comprises:
one or more ceramic and/or metallic powders;
one or more monomers and/or oligomers, and
at least one thermal initiator, capable of generating the initiation of a thermal polymerization under the action of the thermal energy released by said ceramic or metallic material, respectively, during exposure of the latter to at least one source of irradiation chosen from UV, visible or IR irradiation sources.

The ceramic powder(s) may be chosen from oxide ceramic powders, such as lanthanum strontium manganite ceramic, lanthanum strontium manganite ceramic in mixture with yttrium-stabilized zirconia, zirconia, yttrium-stabilized zirconia, ferrite, and non-oxide ceramic powders, such as silicon carbide, silicon nitride and aluminum nitride, while the metal powder(s) may be chosen from silver, copper, iron, tungsten and their alloys, and the ceramic and/or metal powder(s) may be present at a rate of, in particular, 25 to 65 parts by volume relative to the total volume of the composition.

The monomer(s) and/or oligomer(s) may be chosen from polyfunctional (meth)acrylates, such as diethoxylated bisphenol A dimethacrylate, 1,6-hexanediol diacrylate, 3-methyl-1,5-pentanediol diacrylate, trimethylolpropane triacrylate, and mixtures thereof, and may be present, in particular, at a rate of 20 to 50 parts by volume relative to the total volume of the composition.

The thermal initiator(s) may be chosen from:
peroxides, such as tert-amyl peroxybenzoate, benzoyl peroxide, 2,2-bis(tert-butylperoxy)butane, 1,1-bis(tert-butylperoxy)cyclohexane, 2,5-bis(tert-butylperoxy)-2,5-dimethylhexane, 2,5-bis(tert-butylperoxy)-2,5-dimethyl-3-hexyne, bis(1-(tert-butylperoxy)-1-methyl ethyl)benzene, 1,1-bis(tert-butylperoxy)-3,3,5-trimethylcyclohexane, tert-butyl peracetate, tert-butyl peroxide, tert-butyl peroxybenzoate, tert-butylperoxy isopropyl carbonate, cyclohexanone peroxide, dicumyl peroxide, lauroyl peroxide, 2,4-pentanedione peroxide, potassium persulfate and ammonium persulfate;
hydroperoxides, such as tert-butyl hydroperoxide, cumene hydroperoxide and peracetic acid;
alkoxyamines, such as N-(2-methylpropyl)-N-(1-diethylphosphono-2,2-dimethylpropyl)-O-(2-carboxyprop-2-yl)hydroxylamine (BlocBuilder® MA); and
azo compounds, such as 1,1′-azobis(cyclohexanecarbonitrile) and 2,2′-azobisisobutyronitrile (AIBN),

and may be present at a rate of, in particular, 0.5 to 8 parts by volume relative to the total volume of the composition.

The composition according to the invention may also comprise at least one plasticizer chosen, in particular, from polyethylene glycol, dibutyl phthalate, glycerol, in particular at a rate of 5 to 25 parts by volume relative to the total volume of the composition.

The composition according to the invention may also comprise at least one dispersant chosen, in particular, from phosphoric esters, at a rate of, in particular, 1 to 8 parts by volume relative to the total volume of the composition.

The composition according to the invention may also comprise at least one polymerization inhibitor chosen, in particular, from 4-methoxyphenol and phenothiazine, in particular at a rate of 0.1 to 3 parts by volume relative to the total volume of the composition.

The following Examples illustrate the present invention without, however, limiting its scope.

### DESCRIPTION OF THE PREFERRED EMBODIMENTS

### Examples 1 to 6

Suspensions were prepared, the composition of which is given in the following Tables in % by volume of the total volume, and stereolithography tests were carried out at the wavelengths, powers and beam diameters also indicated in the tables. These experiments were carried out with a stereolithography machine of the CERAMAKER type equipped with different lasers.

The results are also shown in each of Tables 1 and 2.

TABLE 1

| | Ex. 1 | Ex. 2 | Ex. 3 | Ex. 4 |
|---|---|---|---|---|
| Ingredients | (comp.) | (comp.) | (invention) | (invention) |
| LSM-8YSZ mixture | 45 | 45 | 45 | 45 |
| (lanthanum strontium manganite - | | | | |
| yttrium- stabilized zirconia ) | | | | |
| in a weight ratio of 50:50 | | | | |
| Diethoxylated bisphenol A | 29 | 29 | 27 | 27 |
| diacrylate (Monomer) | | | | |
| 2-Hydroxy-2-methy1-1-phenyl- | 1 | 1 | 0 | 0 |
| propane-1-one | | | | |
| (Photoinitiator sensitive at 355 nm) | | | | |
| Benzoyl peroxide at 50% by | 0 | 0 | 3 | 3 |
| weight in tricresylphosphate | | | | |
| (thermal initiator) | | | | |
| Beycostat C 213: phosphoric | 5 | 5 | 5 | 5 |
| ester (Dispersant) | | | | |
| Polyethylene glycol 300 | 19 | 19 | 19 | 19 |
| (Plasticizer) | | | | |
| 4-Methoxyphenol | 1 | 1 | 1 | 1 |
| (Polymerization inhibitor) | | | | |
| Wavelength (nm) | 355 | 1064 | 1064 | 355 |
| Power (W) | 3 | 2 | 2 | 3 |
| Beam diameter (mm) | 4 | 4 | 4 | 4 |
| Result | No | No | Manufacture of | Manufacture of |
| | reactivity | reactivity | an object a few | an object a few |
| | | | hundred μm high | hundred μm high |

TABLE 2

| | | Ex. 6 |
|---|---|---|
| Ingredients | Ex. 5 (comp.) | (invention) |
| Silver | 45 | 45 |
| Ethoxylated bisphenol A | 35 | 33 |
| diacrylate (Monomer) | | |
| 2-Hydroxy-2-methy1-1-phenyl- | 2 | 0 |
| propane-1-one | | |
| (Photoinitiator sensitive at 355 nm) | | |
| Benzoyl peroxide at 50% by | 0 | 3 |
| weight in tricresylphosphate | | |
| (Thermal initiator) | | |
| Beycostat C 213: phosphoric | 4 | 4 |
| ester (Dispersant) | | |
| Polyethylene glycol 300 | 14 | 14 |
| (Plasticizer) | | |
| 4-Methoxyphenol | 0 | 1 |
| (Polymerization inhibitor) | | |
| Wavelength (nm) | 355 | 355 |
| Power (W) | 3 | 3 |
| Beam diameter (mm) | 1 | 1 |
| Result | Very low | Manufacture of |
| | reactivity | an object a few |
| | | hundred μm high |

1- Method for manufacturing by stereolithography a green part made of a constituting material, method according to which the layers based on a curable composition comprising:
the constituting material being one of a ceramic material formed by ceramic powder and of a metallic material formed by metallic powder; and
an organic part comprising at least one polymerizable element among a monomer and an oligomer and at least one initiator for the polymerization of the at least one polymerizable element,
are successively cured by the polymerization according to a pattern defined for each layer, the first layer being formed on a construction platform, and each successive layer being formed on the preceding layer and cured on the preceding layer,
wherein as an initiator, at least one thermal initiator is used, the least one thermal initiator being capable of generating the initiation of a thermal polymerization under the action of the thermal energy released by the constituting material, during exposure of the constituting material to at least one irradiation source chosen from an UV source, a visible source and an IR irradiation source.

2- Method according to claim 1, wherein the ceramic powder is chosen among oxide ceramic powders and non-oxide ceramic powders.

3- Method according to claim 1, wherein the polymerizable element is chosen from polyfunctional (meth)acrylates.

4- Method according to claim 1, wherein the thermal initiator is chosen among peroxides, hydroperoxides, alkoxyamines, and azo compounds.

5- Method according to claim 1, wherein a curable composition is used, the curable composition further comprising at least one plasticizer.

6- Method according to claim 1, wherein a curable composition is used, the curable composition further comprising at least one dispersant.

7- Method according to claim 1, wherein a curable composition is used, the curable composition further comprising at least one polymerization inhibitor.

8- Curable composition for implementing the method according to claim 1, wherein the curable composition comprises:
a constituting material formed by at least one of a ceramic powder and of a metallic powder;
at least one polymerizable element chosen among a monomer and a oligomer, and
at least one thermal initiator, capable of generating the initiation of a thermal polymerization under the action of the thermal energy released by the constituting material, during exposure of the constituting material to at least one source of irradiation chosen from an UV source, a visible source and an IR irradiation source.

9- Composition according to claim 8, wherein the ceramic powder is chosen among oxide ceramic powders and non-oxide ceramic powders.

10- Composition according to claim 9, wherein the oxide ceramic powder is chosen among lanthanum strontium manganite ceramic, lanthanum strontium manganite ceramic in mixture with yttrium-stabilized zirconia, zirconia, yttrium-stabilized zirconia and ferrite.

11- Composition according to claim 9, wherein the non-oxide ceramic powder is chosen among silicon carbide, silicon nitride and aluminum nitride.

12- Composition according to claim 8, wherein the metal powder is chosen among silver, copper, iron, tungsten and their alloys.

13- Composition according to claim 8, wherein the at least one polymerizable element is chosen among polyfunctional (meth)acrylates.

14- Composition according to claim 13, wherein the polyfunctional (meth)acrylates are chosen among diethoxylated bisphenol A dimethacrylate, 1,6-hexanediol diacrylate, 3-methyl-1,5-pentanediol diacrylate, trimethylolpropane triacrylate, and mixtures thereof.

15- Composition according to claim 8, wherein the at least one thermal initiator is chosen from peroxides, hydroperoxides, alkoxyamines and azo compounds.

16- Composition according to claim 15, wherein the initiator is benzoyl peroxide.

17- Composition according to claim 8, further comprising at least one plasticizer.

18- Composition according to claim 8, further comprising at least one dispersant.

19- Composition according to claim 8, further comprising at least one polymerization inhibitor.

20- Composition according to claim 8, wherein:
the constituting material is present at a rate of 25 to 65 parts by volume relative to the total volume of the composition;
the at least one polymerizable element is present at a rate of 20 to 50 parts by volume relative to the total volume of the composition;
the at least one initiator is present at a rate of 0.5 to 8 parts by volume relative to the total volume.
